(19) United States
(12) Patent Application Publication
(10) Pub. No.: US 2002/0142500 A1
(43) Pub. Date: Oct. 3, 2002

(54) Ultra-thin interface oxidation by ozonated water rinsing for emitter poly structure

(76) Inventors: Pietro Foglietti, Altdorf (DE); Carl Willis, Freising (DE)

Correspondence Address: Jacqueline J. Garner, Esq., Texas Instruments Incorporated, P.O. Box 655474, M/S 3999, Dallas, TX, 75265, US

(21) Appl. No.: 09/818,329

(22) Filed: Mar. 27, 2001

(51) Int. Cl. H01L 21/00

(52) U.S. Cl. 438/22

(57) ABSTRACT

The present invention relates to a method of forming an interfacial oxide in a bipolar transistor. The method comprises the step of rinsing a wafer having an exposed base region with ozonated deionized water, thereby forming an interfacial oxide layer over the exposed base region.

### FIELD OF THE INVENTION

The present invention relates generally to the field of integrated circuits, and more particularly to a method of fabricating a bipolar transistor device having a stable interface oxide.

### BACKGROUND OF THE INVENTION

It is well known in the art that in NPN bipolar transistors where polycrystalline silicon (polysilicon) is used as the emitter contact to a monocrystalline silicon substrate, a thin film sometimes is formed at the interface between the polysilicon and the silicon substrate, usually in the form of a thin oxide layer. This thin oxide layer can affect substantially the operation of the transistor and impact its current gain. Such a film is typically called an interfacial oxide.

The interfacial oxide tends to have a beneficial impact on the gain of the bipolar transistor. As is generally known, the gain of the transistor (often called the “beta” (β)) is defined as a ratio between the collector current I_{C} and the base current I_{B} (β=I_{C}/I_{B}). Therefore, in order to obtain a high transistor gain, a device designer wants to devise ways in which the collector current I_{C} may be increased, or the base current I_{B} may be decreased, or both. The interfacial oxide has been found to exhibit an advantageous property that its resistance is a function of the type of carrier within the transistor. That is, the interfacial oxide is generally less resistive with respect to majority carriers (electrons) moving from the emitter region of the transistor into the base region than minority carriers (holes) moving from the base region into the emitter region. This phenomena is due to the tunneling probability of electrons being greater than the tunneling probability of holes.

Turning to prior art FIG. 1, an exemplary NPN bipolar transistor 10 is illustrated, wherein a collector region 12 has a base region 14 lying thereover. Insulation regions 16 may be formed on the base region 14 to define a contact region 18 between the base and an overlying emitter region 20. Between the base 14 and the emitter 20, an interfacial oxide 22 is formed. As illustrated in prior art FIG. 2a, electrons 30, the majority carrier in an NPN transistor, can tunnel through the interfacial oxide 22 from the emitter 20 to the base 14, and contribute to the collector current I_{C}.

Conversely, as illustrated in prior art FIG. 2b, the interfacial oxide 22 blocks holes 32 from passing therethrough from the base 14 to the emitter 20, thus working to minimize the base current I_{B}. Therefore the interfacial oxide 22 tends to allow the collector current to be maintained while reducing the base current associated therewith, thereby improving the transistor gain. Thus the interfacial oxide 22, under appropriate circumstances, may be modeled as a selective diode, as illustrated in prior art FIG. 3 and designated at reference numeral 34, wherein the electrons 30 see a forward biased, conductive path, and the holes 32 see a reverse-biased, non-conductive path.

The improvement in transistor gain cited above, however, is substantially dependent upon various properties of the interfacial oxide. For example, for interfacial oxides which are too thick, the number of electrons which can tunnel therethrough from the emitter into the base is reduced substantially, thereby reducing disadvantageously the collector current I_{C}. Likewise, for interfacial oxides which are too thin, an insufficient barrier exists to block the hole current, thereby resulting disadvantageously in an increased base current which reduces transistor gain.

In addition to the thickness of the interfacial oxide being an important characteristic, the oxide integrity also may play a role in device performance. For example, since the interfacial oxide is subject to various types of subsequent thermal processing (e.g., subsequent poly CVD processing, metal deposition, anneal steps, etc.), the interfacial oxide may lose its integrity, that is, the oxide may exhibit non-uniform characteristics spatially thereacross which in some cases may negatively impact the transistor performance. For example, if the interfacial oxide is fractured or becomes discontinuous, resulting in oxide islands, such fractures will be random and not repeatable from device to device; consequently, such fracturing causes unreliable transistor gain performance.

Similarly, oxide re-agglomeration may cause a subsequently formed polysilicon emitter to directly contact the underlying single crystal base region which may result in crystal re-orientation of portions of the poly. An example of such epitaxial realignment is illustrated in prior art FIGS. 4a and 4b, respectively. As illustrated in FIG. 4a, when a uniform, stable oxide interface separates a polysilicon layer having various grain boundaries associated therewith from an underlying single crystal lattice, no realignment takes place. As illustrated in prior art FIG. 4b, however, if the oxide interface exhibits poor integrity, the underlying single crystal lattice may cause a partial realignment of the polysilicon grains.

Such epitaxial realignment of the polysilicon grains may disadvantageously increase hole current by increasing hole recombination efficiency, thereby increasing the base current and decreasing the transistor gain. Furthermore, such epitaxial realignment of polysilicon grains will occur non-uniformly and unpredictably; therefore even if the decrease in gain were acceptable, such degradation would be variable and cause reduced repeatability in transistor performance from device to device.

Therefore there is a need in the art for a method of forming an interfacial oxide with good control which maintains its integrity during subsequent processing.

### SUMMARY OF THE INVENTION

The present invention relates generally to the formation of a tightly controllable interfacial oxide in conjunction with a bipolar transistor, wherein the interfacial oxide maintains exemplary integrity during subsequent thermal processing.

According to one aspect of the present invention, an interfacial oxide is formed over a base portion by rinsing the wafer on which the transistor resides in an ozonated deionized water. Due to the ozone within the deionized water, an interfacial oxide grows slowly over the exposed base region. The interfacial oxide grown in the above manner exhibits excellent uniformity across the exposed base region. In addition, since the interfacial oxide grows slowly, for example, about 8-15 Angstroms over a period of several minutes, a thickness of the interfacial oxide may be tightly controlled by varying an amount of time in which the wafer is rinsed. The resulting interfacial oxide also maintains its integrity upon subsequent thermal processing, thereby providing for a good transistor gain characteristic which is repeatable from device to device and from wafer to wafer.

According to another aspect of the present invention, a method of forming an interfacial oxide is disclosed. The method comprises rinsing a wafer having an exposed region thereon with an ozonated deionized water. The rinsing with the ozonated deionized water causes an interfacial oxide to grow on the exposed base region in a relatively slow and uniform manner, thereby advantageously allowing for excellent oxide thickness control. According to one exemplary aspect of the present invention, an ozone concentration in the deionized water is about 1.6 parts per million and the rinse duration is about 4 minutes to generate an interfacial oxide having a thickness of about 8 Angstroms. Alternatively, however, the ozone concentration may be increased and/or the rinse duration may be extended to generate thicker interfacial oxides, as may be desired.

According to another exemplary aspect of the present invention, forming the interfacial oxide using an ozonated deionized water rinse prior to loading the wafer in the poly deposition chamber allows for an increase in wafer throughput relating to the formation of the interfacial oxide and poly emitter, for example, from about 9 wafers per hour to about 18 wafers per hour. By the above method, growing the interfacial oxide in the polysilicon deposition chamber is eliminated, thereby eliminating a conventional oxidation step associated therewith.

To the accomplishment of the foregoing and related ends, the invention comprises the features hereinafter fully described and particularly pointed out in the claims. The following description and the annexed drawings set forth in detail certain illustrative aspects and implementations of the invention. These are indicative, however, of but a few of the various ways in which the principles of the invention may be employed. Other objects, advantages and novel features of the invention will become apparent from the following detailed description of the invention when considered in conjunction with the drawings.

### BRIEF DESCRIPTION OF THE DRAWINGS

FIG. 1 is a fragmentary cross section diagram illustrating an NPN bipolar transistor having an interfacial oxide associated therewith between the base region and the emitter region thereof;

FIG. 2a is a fragmentary cross section diagram of the NPN bipolar transistor of FIG. 1, wherein the illustration shows how the interfacial oxide permits majority carrier electrons to tunnel therethrough from the emitter to the base, thereby contributing to a collector current of the transistor;

FIG. 2b is a fragmentary cross section diagram of the NPN bipolar transistor of FIG. 1, wherein the illustration shows how the interfacial oxide substantially prohibits minority carrier holes from traversing therethrough from the base to the emitter, thereby acting to reduce a base current associated therewith;

FIG. 3 is a schematic diagram illustrating an exemplary model of the interfacial oxide of FIG. 1, wherein the interfacial oxide behaves as a forward biased, conducting diode with respect to electrons, and behaves as a reverse biased, substantially non-conducting diode with respect to holes;

FIG. 4a is a fragmentary cross section diagram illustrating an oxide interface between an underlying single crystal lattice and an overlying polysilicon layer;

FIG. 4b is a fragmentary cross section diagram illustrating an oxide interface exhibiting poor integrity, and illustrating how the single crystal lattice may cause a grain realignment in the overlying polysilicon layer;

FIG. 5 is a flow chart diagram illustrating a prior art method of forming an interfacial oxide in a bipolar transistor;

FIG. 6 is a flow chart diagram illustrating a method of forming an interfacial oxide in a bipolar transistor according to one exemplary aspect of the present invention;

FIG. 7 is a flow chart diagram illustrating a method of performing an ozonated deionized water rinse of a wafer in conjunction with the formation of an interfacial oxide according to one exemplary aspect of the present invention;

FIGS. 8a-8c are fragmentary SEM photographs illustrating the impact of poor oxide integrity in prior art methods ono poly grain realignment which impacts negatively transistor gain;

FIGS. 9a-9b are fragmentary SEM photographs illustrating an impact of good oxide integrity associated with an interfacial oxide formed in accordance with the present invention; and

FIG. 10 is a flow chart diagram illustrating a method of forming an interfacial oxide in a bipolar transistor according to another exemplary aspect of the present invention.

### DETAILED DESCRIPTION OF THE INVENTION

The present invention will now be described with respect to the accompanying drawings in which like numbered elements represent like parts. The present invention is directed to a method of forming an interfacial oxide in conjunction with the formation of an NPN bipolar transistor. In contrast to conventional methodologies in which the interfacial oxide was formed in a polysilicon deposition apparatus, the present invention forms the interfacial oxide during a water rinse of the wafer after an HF clean step. The water rinse contains deionized water having ozone therein. The ozonated deionized water rinses the wafer and during the rinse, the interfacial oxide grows thereon, wherein a thickness may be a function of the rinse time and the ozone concentration. The resulting interfacial oxide exhibits good uniformity and maintains its integrity after being subjected to various subsequent thermal processing steps.

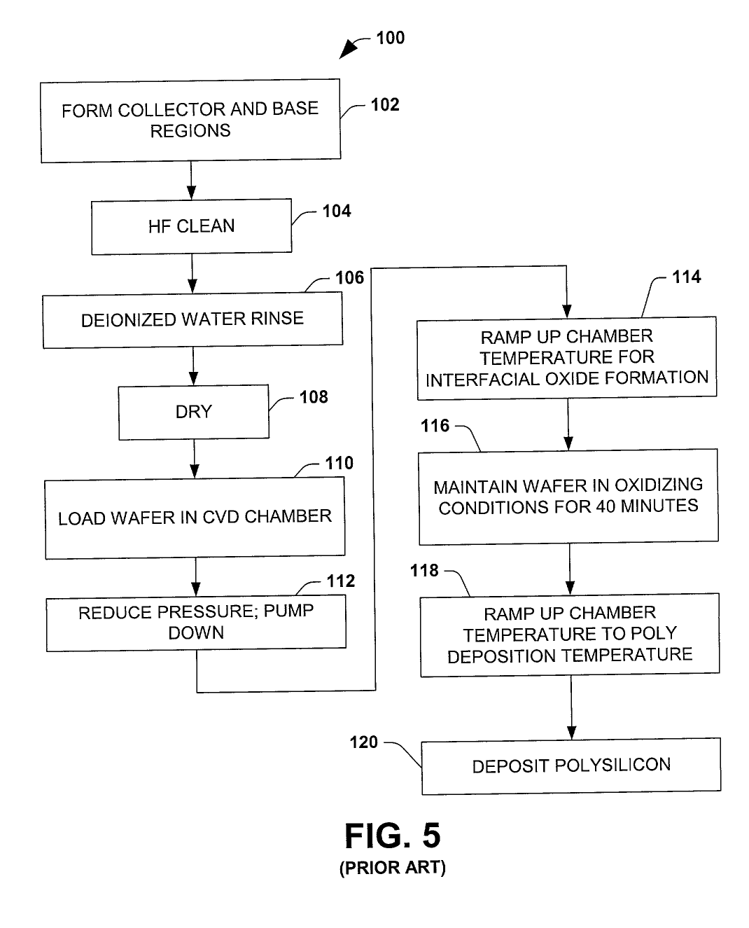

In order to fully understand and appreciate various aspects of the present invention, a brief description is provided below regarding the manner in which conventional interfacial oxides have been fabricated in conjunction with bipolar transistors. With this description, it is believed that the reader will more fully appreciate the advantageous features associated with the present invention. Turning now to prior art FIG. 5, a conventional process flow is illustrated, as designated at reference numeral 100. In the prior art process 100, the collector and base regions of the bipolar transistor are formed in a semiconductor substrate in any manner of known ways at step 102, as may be desired. The formation of the base region is followed by an HF clean at step 104, wherein a hydrofluoric solution is applied to the wafer to remove any native oxides, particulates, or residue contaminants which may be residing thereon.

The HF clean step is followed by an immersion or rinsing of the wafer in deionized water at step 106. The water rinse of step 106 is employed typically to remove any remaining HF and/or other undesired elements which may remain on the wafer surface after the HF clean. The water rinse is then typically followed by step 108, wherein the wafer is dried. The dried wafer is then loaded into a polysilicon deposition chamber, for example, a chemical vapor deposition (CVD) apparatus at step 110.

The wafer is loaded into the poly deposition chamber at a chamber temperature of about 400° C. at step 110. The pressure is then reduced, for example, by evacuating the chamber at step 112. Once the minimum pressure is reached (e.g., about 2-3 mTorr), the temperature of the chamber is then increased to a target oxidation temperature of about 500° C. at step 114 and the wafer is then maintained in the chamber at that temperature in the presence of an oxidizing environment, for example, an O₂/Ar mixture (5% Ar) for about 40 minutes at step 116. During this time in step 116, an interfacial oxide forms over the exposed base region.

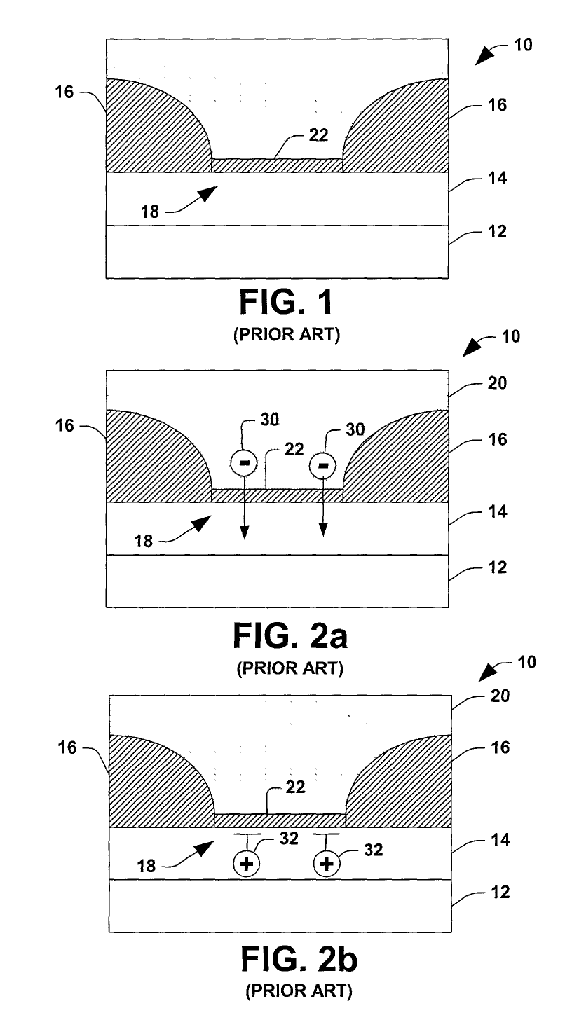

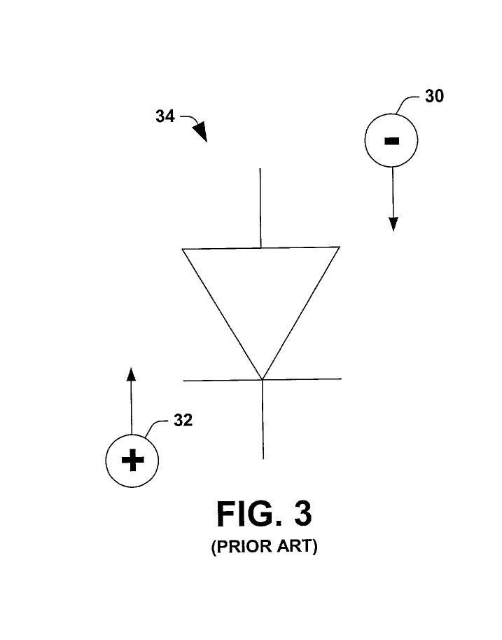

After the formation of the interfacial oxide at step 116, the method 100 continues at step 118, wherein the polysilicon deposition chamber temperature is increased to about 630° C. and a polysilicon film deposition takes place at step 120 via, for example, CVD. Subsequently, the poly may be patterned to define an emitter overlying the base region having the interfacial oxide layer therebetween (see, e.g., prior art FIG. 1).

The interfacial oxide formed in the process 100 described above suffers from various problems. Initially, it has been found that the resulting oxide does not maintain its integrity upon being exposed to subsequent thermal processing. For example, the oxide has been found to fracture, etc., as discussed supra in the background. In addition to poor integrity maintenance, the interfacial oxide of method 100 does not exhibit good thickness uniformity from wafer to wafer, thereby resulting in transistor devices having gain characteristics which undesirably vary substantially.

Poor interfacial oxide uniformity in the process 100 is due to several reasons. For example multiple wafers are typically loaded into the poly deposition chamber at one time. Due to variable loading influences within the chamber, the temperature profile in the chamber during oxidation is not uniform, which contributes to some wafers exhibiting more or less oxidation than other wafers. Further, the oxygen concentration within the chamber during oxidation also varies spatially therein. In addition, the relatively high partial pressure of water concentration still present within the chamber, even at high vacuum, comes from various components spatially distributed therein. The water vapor content in the chamber is thus variable spatially and further impacts the rate of oxidation among the various wafers in the chamber during the oxidation process.

In addition, such water vapor concentration may vary widely from batch to batch of wafers since the water vapor content therein is substantially different immediately after a maintenance or cleaning thereof than after multiple batches of wafers loaded therein. These and other factors tend to cause significant variations in the interfacial oxide which, as described supra, have a negative influence on transistor gain repeatability from one device to another.

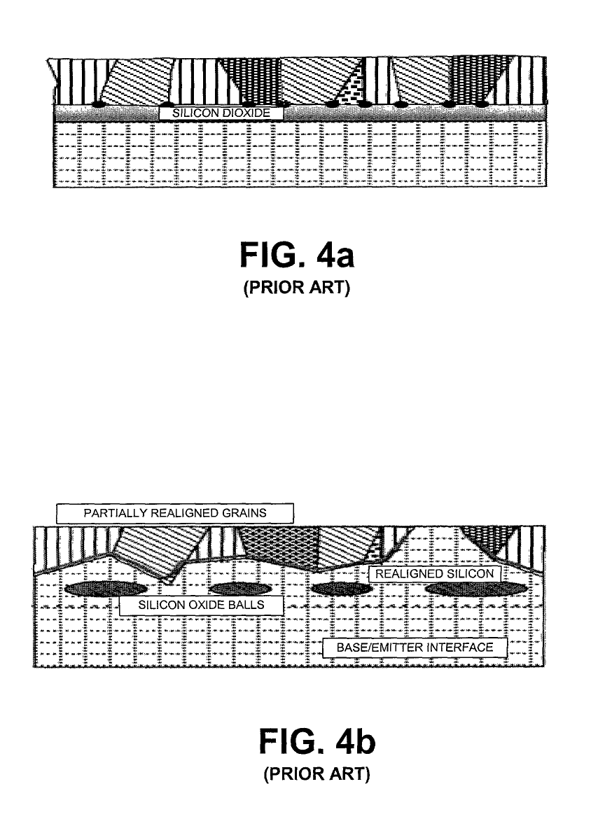

The method of the present invention overcomes the disadvantages associated with the conventional process 100 of FIG. 4 and additionally provides an increase in throughput associated with the poly deposition apparatus. These and other advantages associated with the present invention will be more fully appreciated in conjunction with the description below.

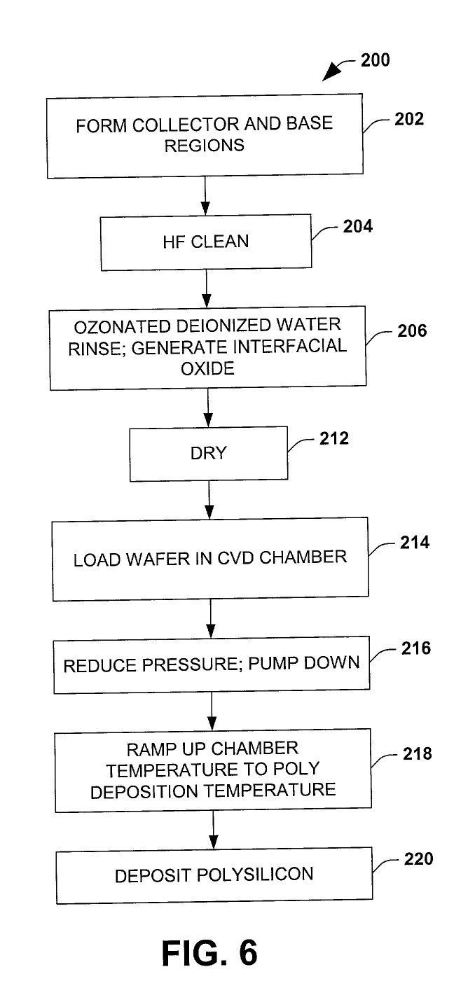

Turning now to FIG. 6, a flow chart is provided illustrating a method 200 of forming an interfacial oxide in conjunction with the fabrication of a bipolar transistor. The method 200 may operate at steps 202 and 204 in much the same way as steps 102 and 104 of prior art FIG. 5, in order to prepare the exposed portion of the base region for oxidation. Alternatively, however, various methods of forming the collector and base regions and cleaning the exposed portion of the base region may be employed and all such methods are contemplated as falling within the scope of the present invention.

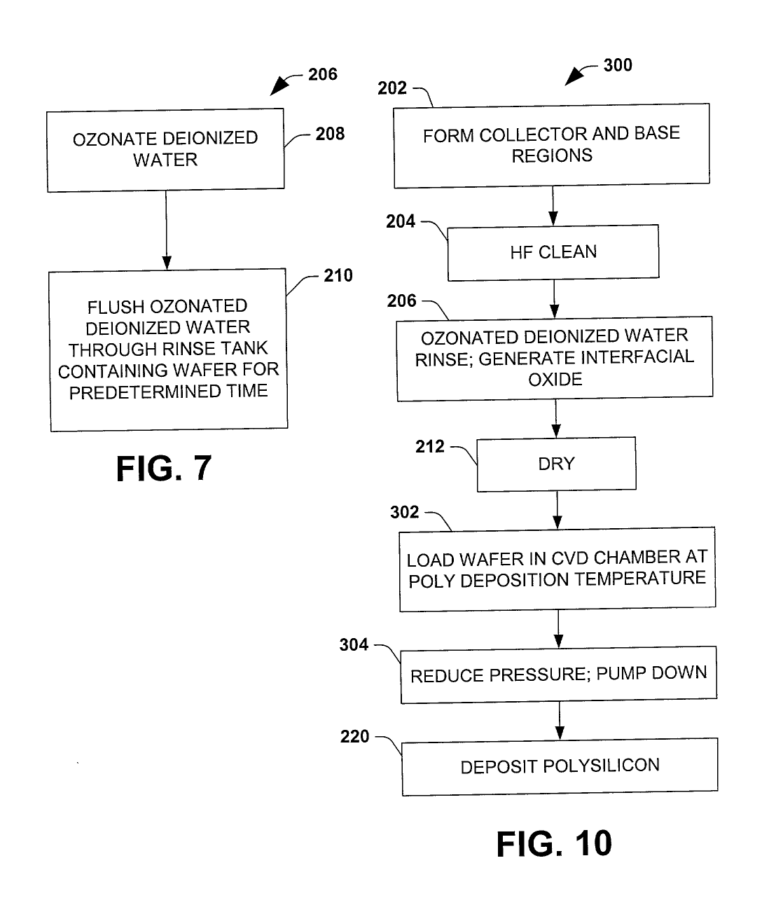

Subsequently, at step 206, an ozonated deionized water rinse is employed to both remove any remaining HF or other contaminates as well as to form an interfacial oxide over an exposed portion of the base region. According to one exemplary aspect of the present invention, the rinse step 206 may be carried out in accordance with the flow chart of FIG. 7. For example, step 206 may include a step 208 of ozonating a quantity of deionized water. Such an ozonation step may include, for example, applying an electrical charge to an oxygen source to generate ozone and then ozonating the quantity of deionized water via hydration. That is, ozone gas may be permitted to bubble up through a quantity of deionized water in a controlled fashion in order to establish a predetermined ozone concentration. Although one manner of generating ozonated deionized water has been described above, it is understood that other methods and procedures may be employed to generate a quantity of ozonated deionized water with various ozone concentrations associated therewith, and such alternatives are contemplated as falling within the scope of the present invention.

Once the ozonated deionized water is formed at step 208, the ozonated deionized water may be flushed through a rinse tank at step 210 containing a wafer having an exposed base region portion associated therewith. The amount of time in which the ozonated deionized water contacts the exposed wafer may be a predetermined period of time based on a desired thickness of the interfacial oxide layer and the ozone concentration within the deionized water.

According to one exemplary aspect of the present invention, the ozone concentration within the deionized water is about 1.6 parts per million, and with such a concentration a flush time of about 4 minutes provides an interfacial oxide having a thickness of about 8 Angstroms. Alternatively, the ozone concentration within the deionized water may be varied. After preliminary testing, it is apparent that with ozone concentrations in the range of about 1-15 parts per million, interfacial oxides having thicknesses of about 8-15 Angstroms may be formed over a span of about ten minutes or less.

The slow rate at which the interfacial oxide grows in the ozonated deionized water flush of the present invention advantageously increases the control by which the oxide may be grown. That is, since the oxide grows over a period of minutes, rather than seconds, varying a time associated with the rinse allows one to control tightly the thickness of the interfacial oxide layer, as may be desired. In addition, since the ozone concentration may also be varied in an easily controlled manner, another degree of freedom in controlling the interfacial oxide formation is provided by the present invention.

Returning now to FIG. 6, the method 200 continues at step 212 after the rinse by drying the wafer, for example by subjecting the wafer to a heated isopropyl alcohol vapor. The wafer (typically along with other wafers) is then loaded into the poly deposition chamber, for example, a CVD chamber at about 400° C. at step 214. The pressure in the chamber is then reduced down to about 2-3 mTorr at step 216. The chamber temperature is then ramped up to a higher temperature for polysilicon deposition, for example, about 630° C. at step 218, and the polysilicon deposition then may take place via CVD or other techniques, as may be desired, at step 220.

Note that in the method 200 of FIG. 6, a two step temperature ramping process (see, e.g., steps 114-118 in prior art FIG. 5) is eliminated because the interfacial oxide is not grown in the poly deposition chamber. Therefore the additional time required in the prior art to achieve temperature stabilization within the chamber for two separate temperatures is eliminated. In addition, the time duration needed to generate the interfacial oxide in accordance with one aspect of the present invention is about 4 minutes or so compared to the prior art method 100 of FIG. 5, wherein the oxidation period lasts about 40 minutes. Accordingly, the present invention provides an increase in wafer throughput in the polysilicon deposition chamber over the prior art from about 9 wafers per hour to about 18 wafers per hour.

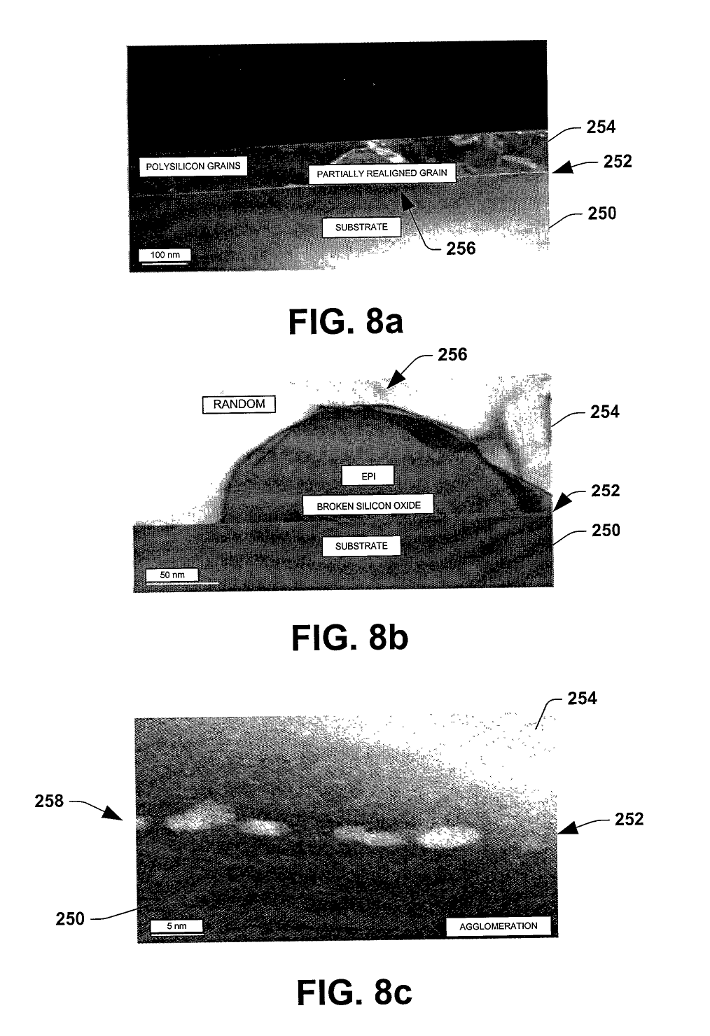

Not only does the method 200 of the present invention provide increased throughput and good interfacial oxide thickness control, but it has been found by the inventors of the present invention that the interfacial oxide generated by ozonated deionized water rinsing results in a higher quality oxide that better maintains its integrity after thermal processing than prior art oxides. For example, in FIGS. 8a-8c, SEM photographs show a prior art interfacial oxide which is agglomerated and/or fractured, thereby resulting in a realignment of grains in the polysilicon.

In FIG. 8a, a single crystal substrate 250 has a thin oxide 252 formed thereover via the prior art process of FIG. 5. A polysilicon layer 254 overlies the oxide 252. Note that in FIG. 8a, a region 256 exists in which a portion of the polysilicon layer has experienced grain realignment due to contact with the underlying single crystal substrate 250. FIG. 8b is an enlarged view of a portion of FIG. 8a, wherein the region 256 of the polysilicon layer 254 experiencing realignment is illustrated in greater detail. Such realignment is due to an agglomeration of the interfacial oxide resulting in oxide islands, as illustrated in FIG. 8c and designated at reference numeral 258.

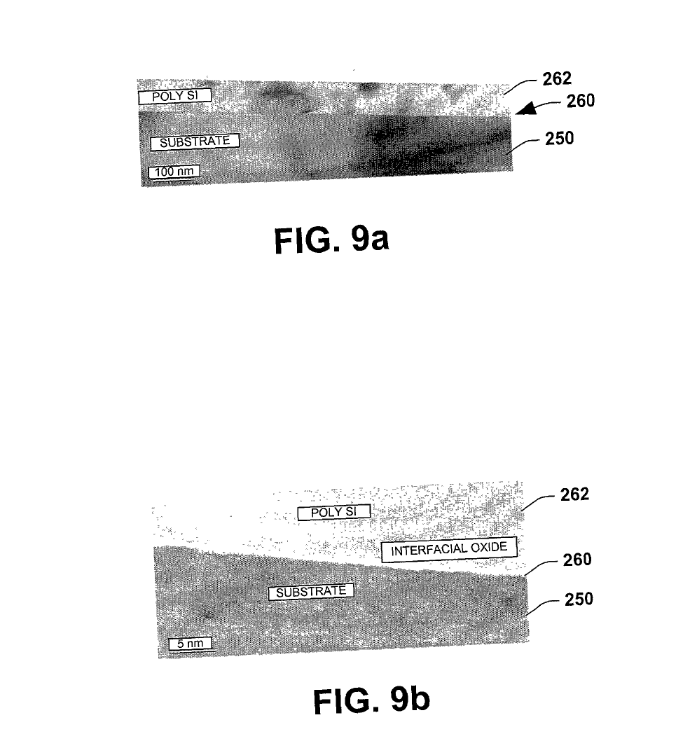

In stark contrast to the poor oxide integrity illustrated in FIGS. 8a-8c, FIGS. 9a-9b illustrate exemplary SEM cross sections of interfacial oxides fabricated in conjunction with an ozonated deionized water rinse in accordance with the present invention. Turning to FIG. 9a, the wafer has the single crystal substrate 250 and an interfacial oxide 260 formed thereon in accordance with the present invention and a polysilicon layer 262 lies thereover. FIG. 9b is an enlarged view of FIG. 9a which illustrates the interfacial oxide layer 260 in greater detail. Note that in FIGS. 9a-9b, the interfacial oxide 260 has not agglomerated, and has maintained its integrity despite the thermal processing associated with the poly deposition. Consequently, none of the polysilicon grains assume the orientation of the underlying substrate 250, that is, no grain realignment is observed in the polysilicon 262. Consequently, hole current associated therewith is minimized and the transistor gain is increased. In addition, due to the good interfacial oxide uniformity, the transistor gain is substantially repeatable from wafer to wafer.

According to another aspect of the present invention, a method of forming a bipolar transistor having an interfacial oxide associated therewith is provided, as designated at reference numeral 300. The method 300 may proceed in the same fashion as method 200 of FIG. 6 with regard to steps 202-212, as may be desired. At that point, an interfacial oxide has been formed on an exposed base region of the wafer via an ozonated deionized water rinse. At step 302, the oxidized wafer is loaded into the poly deposition chamber at the poly deposition temperature (e.g., about 630° C.) instead of at a lower temperature (e.g., about 400° C.) as in method 200. Previously, placing wafers into the deposition chamber at a lower temperature was advisable for loading considerations, wherein the temperature change would not be too great so as to induce a change on the wafer surface. This concern was particularly relevant when no oxide was yet formed on the wafer since subsequent oxidation uniformity, etc., may be further degraded due to any changes or non-uniformities on the single crystal semiconductor surface.

According to the present invention, an interfacial oxide already has been formed on the wafer at step 206 and the oxide has been shown to maintain its integrity with respect to subsequent thermal processing. Accordingly, it is believed that a wafer loading of about 630° C. (e.g., about the poly deposition temperature) may be acceptable to the oxidized wafer. Therefore step 214 of FIG. 6 may be eliminated, thereby further improving the wafer throughput. The method 300 then continues at steps 304 and 220, wherein the pressure is reduced in the chamber and then polysilicon is deposited over the interfacial oxide as part of the step of forming the transistor emitter region.

Although the invention has been shown and described with respect to a certain aspect or various aspects, it is obvious that equivalent alterations and modifications will occur to others skilled in the art upon the reading and understanding of this specification and the annexed drawings. In particular regard to the various functions performed by the above described components (assemblies, devices, circuits, etc.), the terms (including a reference to a “means”) used to describe such components are intended to correspond, unless otherwise indicated, to any component which performs the specified function of the described component (i.e., that is functionally equivalent), even though not structurally equivalent to the disclosed structure which performs the function in the herein illustrated exemplary embodiments of the invention. In addition, while a particular feature of the invention may have been disclosed with respect to only one of several aspects of the invention, such feature may be combined with one or more other features of the other aspects as may be desired and advantageous for any given or particular application. Furthermore, to the extent that the term “includes” is used in either the detailed description or the claims, such term is intended to be inclusive in a manner similar to the term “comprising.”

What is claimed is:

1. A method of forming an interfacial oxide in a bipolar transistor, comprising the step of rinsing a wafer having an exposed base region with ozonated deionized water, thereby forming an interfacial oxide layer over the exposed base region.

2. The method of claim 1, wherein the ozonated deionized water comprises an ozone concentration of about 1.6 parts per million.

3. The method of claim 2, wherein the step of rinsing the wafer continues for a duration of about 4 minutes.

4. The method of claim 1, wherein the interfacial oxide layer has a thickness of about 8 Angstroms to about 15 Angstroms.

5. A method of forming a bipolar transistor having an interfacial oxide layer associated therewith, comprising the steps of:
forming a collector region in a substrate of a wafer;
forming a base region over the collector region.
cleaning the wafer to remove contaminants or native oxides on a portion of the base region;
rinsing the wafer with ozonated deionized water, thereby forming an interfacial oxide layer over the portion of the base region;
forming an emitter region over the base region, wherein the interfacial oxide permits electrons to flow from the emitter to the base and substantially prohibits holes from flowing from the base to the emitter, thereby enhancing a gain of the bipolar transistor.

6. The method of claim 5, wherein the ozonated deionized water comprises an ozone concentration of about 1.6 parts per million.

7. The method of claim 6, wherein the step of rinsing continues for a duration of about 4 minutes.

8. The method of claim 5, wherein the interfacial oxide has a thickness of about 8 Angstroms to about 15 Angstroms.

9. The method of claim 5, wherein the step of rinsing the wafer with ozonated deionized water comprises:
hydrating deionized water with an ozone source;
placing the wafer in a rinse tank; and
pouring the ozonated deionized water over the wafer in the rinse tank, wherein a waste ozonated deionized water in the rinse tank is collected.

10. The method of claim 9, wherein hydrating deionized water with an ozone source comprises:
applying an electrical charge to an oxygen source to generate an ozone source; and
coupling the ozone source to deionized water, wherein a rate of ozone diffusing into the deionized water is a function of a flow rate of the ozone source.

11. The method of claim 5, further comprising drying the wafer after rinsing the wafer with ozonated deionized water.

12. The method of claim 5, further comprising the steps of:
loading the wafer into a polysilicon deposition chamber having a chamber temperature of about 400° C.; and
maintaining the wafer in the polysilicon deposition chamber at the temperature of about 400° C. for about 1 hour.

13. The method of claim 12, further comprising reducing a pressure in the polysilicon deposition chamber after maintaining the wafer therein for about 1 hour.

14. The method of claim 13, further comprising increasing the temperature in the polysilicon deposition chamber to a temperature of about 630° C.

15. The method of claim 14, wherein forming the emitter region comprises:
depositing a polysilicon film over the wafer using the polysilicon deposition chamber at the temperature of about 630° C.; and
selectively etching the polysilicon film, wherein a remaining portion thereof forms the emitter region.

16. A method of forming a bipolar transistor having an interfacial oxide layer associated therewith, comprising the steps of:
forming a collector region in a substrate of a wafer;
forming a base region over the collector region.
cleaning the wafer with an HF solution to remove contaminants or native oxides on a portion of the base region;
rinsing the wafer with ozonated deionized water, thereby forming an interfacial oxide layer over the portion of the base region;
drying the rinsed wafer using a heated isopropyl alcohol vapor;
forming an emitter region over the base region, wherein the interfacial oxide permits electrons to flow from the emitter to the base and substantially prohibits holes from flowing from the base to the emitter, thereby enhancing a gain of the bipolar transistor.

17. The method of claim 16, wherein forming the emitter region comprises:
loading the wafer into a polysilicon deposition chamber having a chamber temperature of about 400° C.;
maintaining the wafer in the polysilicon deposition chamber at the temperature of about 400° C. for about 1 hour;
reducing a pressure in the polysilicon deposition chamber after maintaining the wafer therein for about 1 hour;
increasing the temperature in the polysilicon deposition chamber to a temperature of about 630° C.;
depositing a polysilicon film over the wafer using the polysilicon deposition chamber at the temperature of about 630° C.; and
selectively etching the polysilicon film, wherein a remaining portion thereof forms the emitter region.

18. The method of claim 16, wherein forming the emitter region comprises:
loading the wafer into a polysilicon deposition chamber having a chamber temperature of about 630° C.;
reducing a pressure in the polysilicon deposition chamber;
depositing a polysilicon film over the wafer using the polysilicon deposition chamber at the temperature of about 630° C.; and
selectively etching the polysilicon film, wherein a remaining portion thereof forms the emitter region.
